(19) United States
(12) Patent Application Publication
(10) Pub. No.: US 2008/0246547 A1
(43) Pub. Date: Oct. 9, 2008

(54) Method And System for Output Matching of Rf Transistors

(75) Inventor: Igor Blednov, Nijmegen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/909,059

(22) PCT Filed: Mar. 14, 2006
(86) PCT No.: PCT/IB2006/050791

§ 371 Date: Jun. 3, 2008

(30) Foreign Application Priority Data
Mar. 18, 2005 (EP) 05102130.1

(51) Int. Cl. H03L 5/00; H01Q 17/00

(52) U.S. Cl. 331/109; 29/601

(57) ABSTRACT

A high frequency power device (100) is described comprising a high frequency power transistor (102) having a first main electrode, a second main electrode acting as output electrode and a control electrode, and an output compensation circuit (104) for compensating parasitic output capacitance of the transistor (102). The output compensation circuit is physically positioned relative to the transistor such that a shorter bond wire between the output electrode of the transistor and an output lead of the high frequency power device is obtained. The output compensation circuit (104) therefore is physically located in between an input lead (108) of the high frequency power device (100) and the transistor (102). The inductance introduced by the bond wire Lcomp from the output compensation circuit (104) to the output electrode of the transistor (102) can be used as a feedback signal. Selection of the mutual inductive coupling between the bond wire LcOmP and a bond wire connected to the pre-matching circuit (106) allows to further optimize the properties of the high frequency power device.

The present invention relates to the field of radiofrequency (RF) devices and methods of making and operating the same. More specifically, the present invention relates to RF devices comprising an output compensation circuitry, such as e.g. for RF transistors.

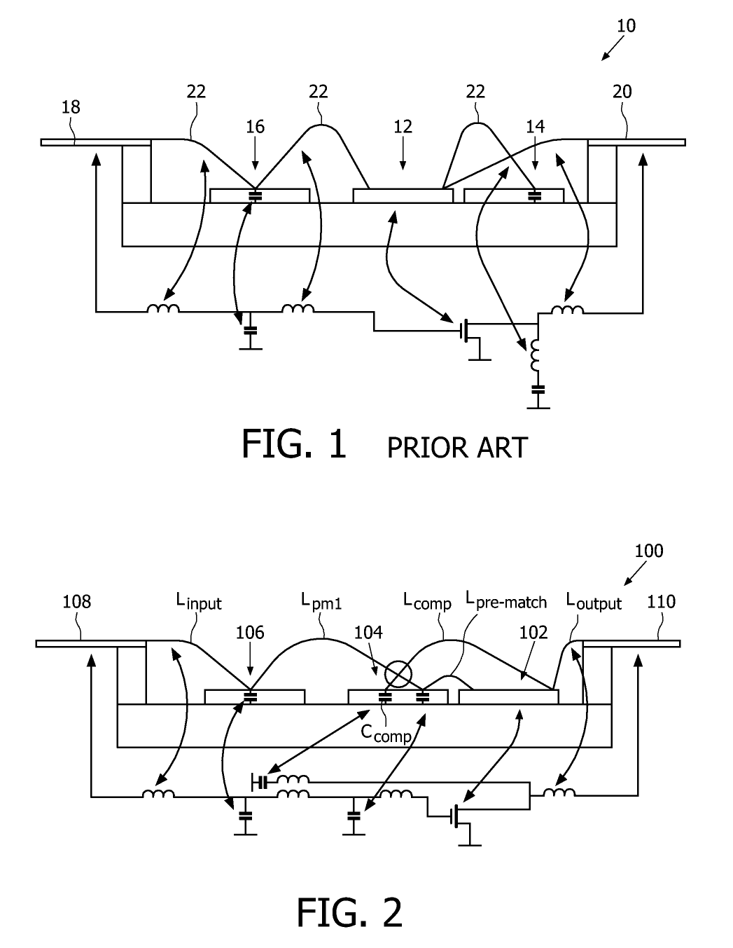

Radiofrequency (RF) transistors, e.g. medium frequency or high frequency power transistors, are widely used. These devices typically suffer from parasitic output capacitance Cₒᵤₜ, which limits their operational bandwidth, their power efficiency and their power gain. The latter problem is typically solved by adding a compensation element, which often is a compensation inductance or Internal Shunt Inductance, called INSHIN. The compensation element typically is attached between the RF device's output and the ground through a decoupling capacitor. In this way, a parallel resonance is provided with the parasitic output capacitance Cₒᵤₜ at the operational frequency, allowing to create an increased output impedance of the device having a low imaginary part, which helps for better matching of the device output to the load in the required frequency band. A typical design for such an output compensation circuitry is presented in FIG. 1, showing a RF device 10 comprising a RF transistor 12, e.g. a RF power transistor, an output compensation circuit 14 and a pre-matching circuit 16. The RF device 10 also comprises an input lead 18 and an output lead 20. Different interconnections between the components are provided with bond wire(s) 22. Optimization of the RF power device using an output compensation circuit has been described e.g. in patent application WO 02/058149 A1, describing an output compensation stage comprising two capacitors thus allowing to obtain a double internal post-matching of the transistor. An advantage thereof is that the chance of mutual inductive coupling between the output compensation stage and the bond wire between the output electrode of the transistor and the output lead is reduced, providing a better output compensation.

Nevertheless, in the above described prior art systems, the bond wire lengths are significant in length and also their equivalent parasitic inductance value for the bond wire(s) connecting the output of the transistor die to the output lead cannot be reduced below a certain value. This parasitic inductance has a negative impact on several operational aspects of the device, such as e.g. the operational bandwidth, the power efficiency, the reliability, the obtainable gain and maximum power, etc.

It is an object of the present invention to provide an electronic RF device with an output compensation circuit which has an improved RF performance, such as improved power gain and power efficiency at RF frequencies. It is a further object to provide a method of manufacturing such an electronic RF device.

The above objective is accomplished by a method and device according to the present invention.

The invention relates to a electronic RF device, the electronic RF device comprising an input lead and an output lead, a transistor and an output compensation circuit for compensating a parasitic output capacitance Cₒᵤₜ of the transistor, the output compensation circuit being physically located between the input lead and the transistor. The electronic RF device may generate an RF power. With “physically located” is meant “being positioned”. “The output compensation circuit being physically located between the input lead and the transistor” may mean that “a decoupling capacitor of the output compensation circuit is positioned closer to, i.e. at a shorter distance from, the input lead of the electronic RF than an output electrode of the transistor”. Making the physical position of the output compensation circuit between the input lead and the transistor can allow a significant decrease in the length of the bond wire(s) connecting the output electrode of the transistor with the output lead of the electronic RF device. The reduction of the length of these bond wire(s) can allow to obtain a better bandwidth, i.e. for example a broader bandwidth, using the RF devices. The reduction of the length of these bond wire(s) also can allow to improve the thermal power dissipation, thus resulting in a more reliable device. It is furthermore an advantage of the specific design that a higher power efficiency can be obtained compared to prior art devices having an output compensation circuit physically located between the transistor and the output lead of the device.

The transistor may comprise a first main electrode, a second main electrode which is an output electrode and a control electrode, wherein the output electrode is connected to the output lead with bond wire(s) Lₒᵤₜₚᵤₜ. In case of a unipolar transistor, the first main electrode may be a source electrode, the second main electrode may be a drain electrode and the control electrode may be a gate electrode. The transistor may be a laterally diffused metal-oxide semiconductor transistor. Thus, the control electrode may be the gate electrode of a lateral diffused metal-oxide semiconductor transistor. It is an advantage of the RF device, e.g. RF power device, comprising the suggested output compensation circuit configuration that a better power scaling versus the control electrode width, e.g. gate electrode width W_{g}, of the transistor and a higher output electrode efficiency can be obtained. It is an advantage that the RF devices can be based on standard components, such as e.g. an LDMOS transistor.

The output compensation circuit and the transistor may be located on a single die. It is an advantage that the RF devices, e.g. RF power device, can be provided with a compact system design, such that the space required for the device in the package is small. It is also an advantage that the devices can be made more easily, as processing on a single die can be performed. The needed substrate size also may be reduced, resulting in a lower cost.

The output compensation circuit may comprise a capacitor C_{Comp}, the capacitor C_{Comp} being connected to the output electrode of the transistor with bond wire(s) L_{Comp}. It is an advantage of the RF devices that a standard output compensation circuit, such as e.g. an INSHIN circuit, can be used. The use of standard components allows a lower production cost.

An inductance determined by the bond wire(s) L_{Comp} may be used as a source of feedback signal. Such feedback signals can be advantageously used for optimizing the quality of operation of the RF devices.

The electronic device furthermore may comprise a pre-matching circuit, connected to the control electrode with bond wire(s) L_{pre match}. It is an advantage of the RF devices that pre-matching circuits can be provided, allowing to obtain an improved input impedance range, e.g. an extended impedance range.

A mutual inductance coupling between the bond wire(s) L_{Comp} and the bond wire(s) L_{pre match} may be used as part of a feedback mechanism. The pre-matching circuit may comprise a number of components interconnected by bond wire(s) Lₚₘᵢ, wherein a mutual inductance coupling between the bond wire(s) L_{Comp} and one of the bond wire(s) Lₚₘᵢ may be used as part of a feedback mechanism. It is advantageous that feedback mechanisms can be provided, resulting in improved signal processing. It furthermore is advantageous that different feedback mechanisms can be provided, allowing optimization of selectable specific characteristics of the signal processing.

The electronic device furthermore may comprise an additional transformation circuit. Due to the compact design of the RF devices, additional transformation circuits may be provided which allows to obtain an improved signal processing.

The invention also relates to a method of manufacturing an electronic RF device, the method comprising providing a substrate, providing an input lead and an output lead of the electronic RF device, an RF transistor and an output compensation circuit and providing bond wire(s) between the output compensation circuit and an output electrode of the RF transistor and between the output electrode of the RF transistor and the output lead, wherein providing an RF transistor and an output compensation circuit comprises positioning the output compensation circuit physically between the input lead and the RF transistor. The output compensation circuit may be physically positioned between the input lead and the RF transistor die. The RF transistor may be an RF power transistor. The RF power transistor may be of any kind, such as e.g. a metal-oxide semiconductor field-effect transistor (MOSFET), a lateral diff-used metal-oxide semiconductor transistor (LDMOST), a bipolar junction transistor (BJT), a junction field effect transistor (JFET) or a heterojunction bipolar transistor (HBT). The electronic RF device may generate RF power. It is an advantage of the method of manufacturing that standard components can be used. It is also an advantage of the method that standard semiconductor processing techniques can be used.

The method furthermore may comprise providing a pre-matching circuit connected to a control electrode of the RF transistor and selecting a degree of mutual inductive coupling between the bond wire(s) L_{comp} and a bond wire(s) connected to the pre-matching circuit. It is advantageous that the method of manufacturing allows an easy selection of the optimum feed-back mechanism used in the RF device, e.g. as a function of the parameters of the signal processing to be optimized.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature. The teachings of the present invention permit the design of improved RF, e.g. medium frequency or high frequency, devices, such as e.g. RF power devices.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference Figures quoted below refer to the attached drawings.

FIG. 1—prior art is a schematic cross-sectional representation and a corresponding symbol circuit diagram illustrating the equivalent electrical circuit of a RF device comprising an output compensation circuit physically located near the output electrode of the transistor as known from the prior art.

FIG. 2 is a schematic cross-sectional representation and a corresponding symbol circuit diagram illustrating the equivalent electrical circuit of a first alternative design of an RF device comprising an output compensation circuit physically located at the input side of the transistors according to a first embodiment of the present invention.

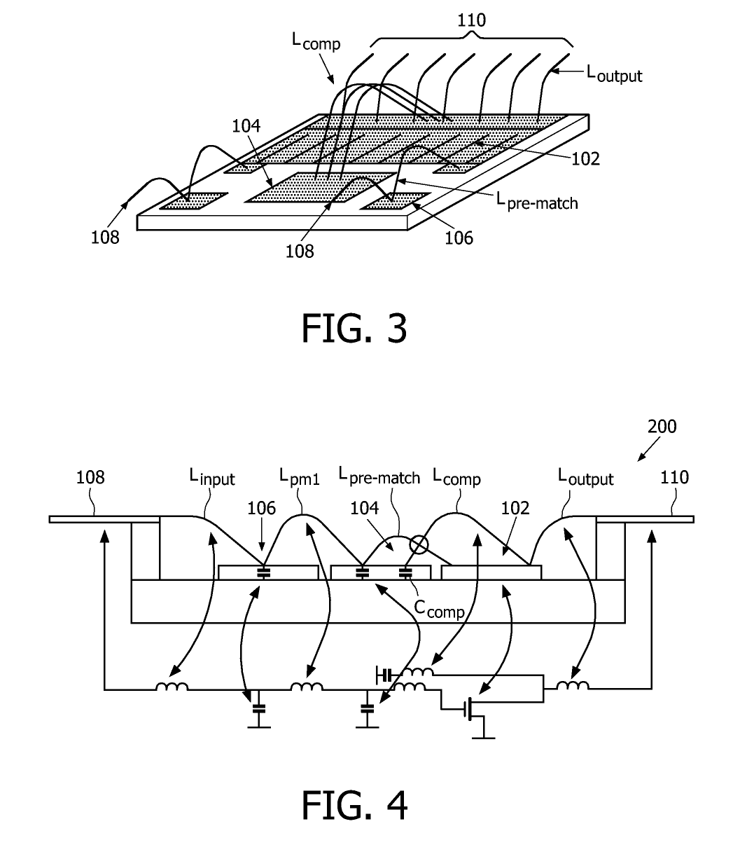

FIG. 3 is a schematic representation of a second alternative design of an RF device comprising an output compensation circuit physically located at the input side of the transistor according to a first embodiment of the present invention.

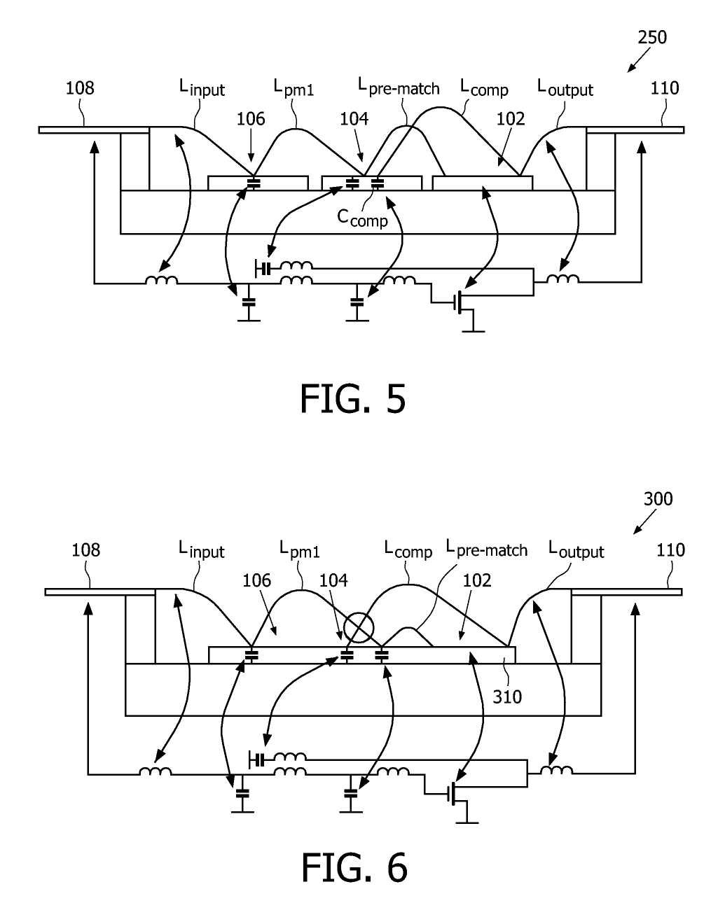

FIG. 4 and FIG. 5 show a schematic cross-sectional representation and a corresponding symbol circuit diagram illustrating the equivalent electrical circuit of a third and fourth alternative design of an RF device comprising an output compensation circuit physically located at the input side of the transistor according to a first embodiment of the present invention.

FIG. 6 shows a schematic cross-sectional representation and a corresponding symbol circuit diagram illustrating the equivalent electrical circuit of an RF device wherein all components are integrated on a single die, according to a second embodiment of the present invention.

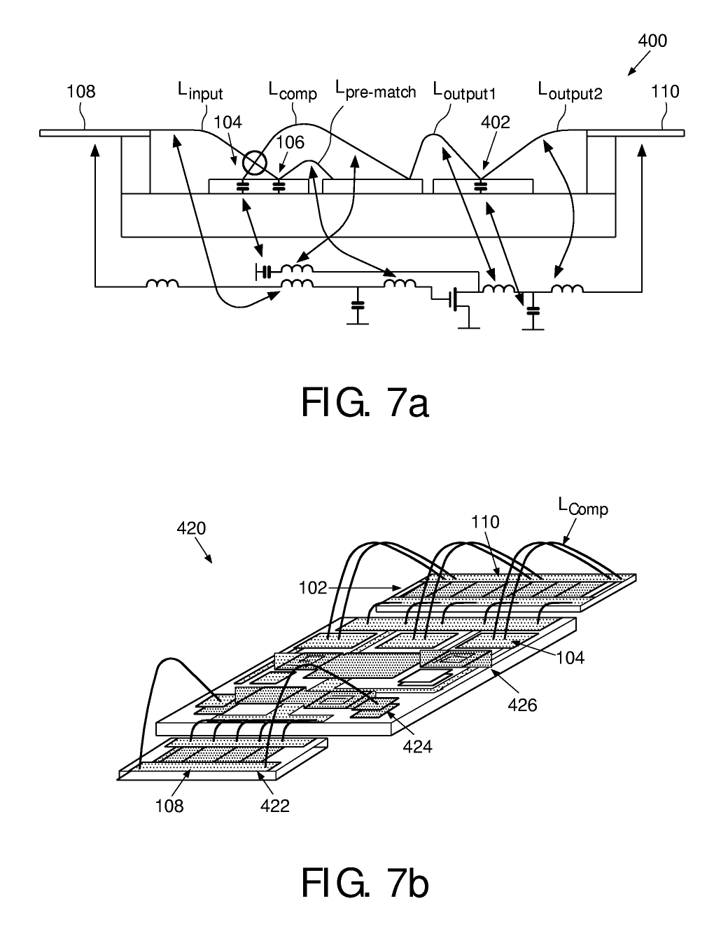

FIG. 7a shows a schematic cross-sectional representation and a corresponding symbol circuit diagram illustrating the equivalent electrical circuit of an RF device comprising an additional transforming circuit at the output according to a fourth embodiment of the present invention.

FIG. 7b shows a schematic illustration of an example of a two stage amplification device arranged in a single standard discrete device package, according to a fourth embodiment of the present invention.

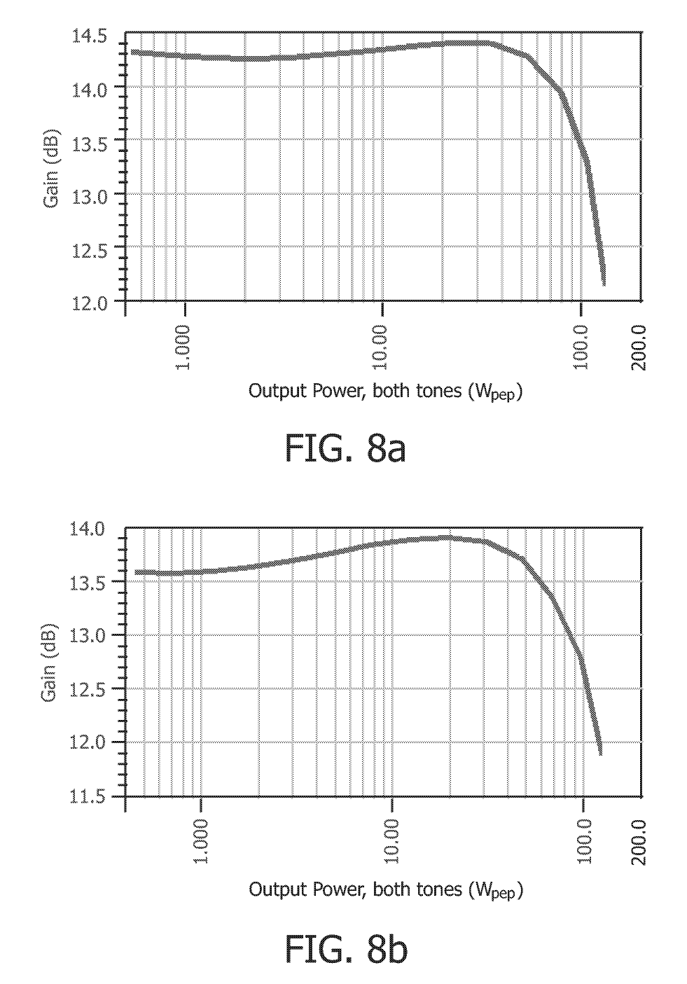

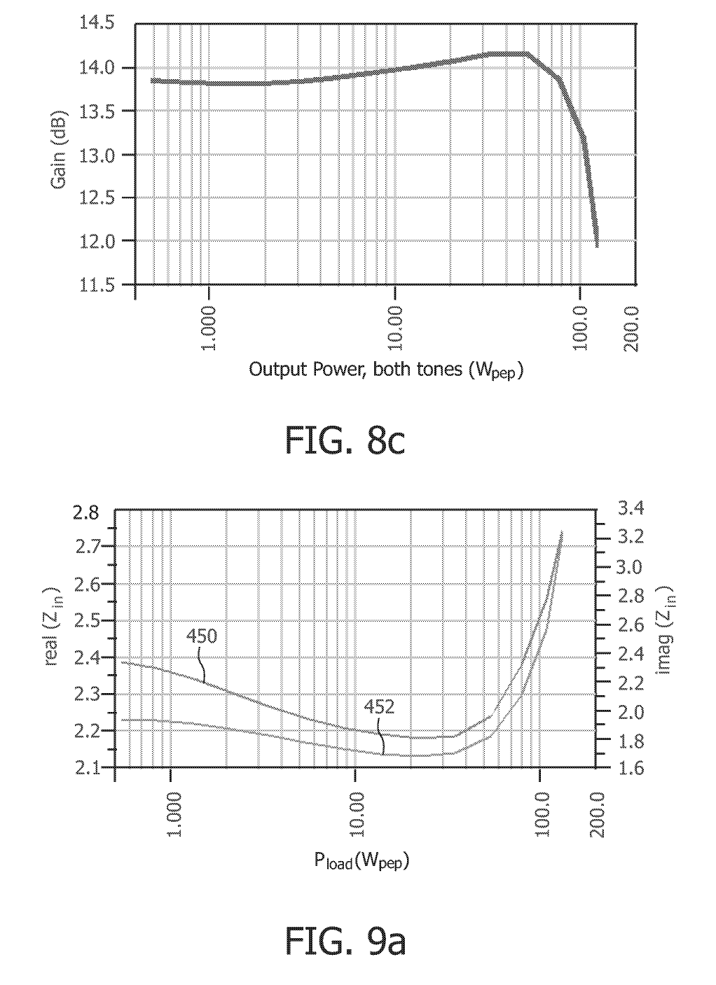

FIG. 8a to FIG. 8c show a simulated result for the obtained gain as a function of the output power in a 40W LDMOST model having different degrees of mutual inductive coupling between a pre-matching circuit and an output compensation circuit in an RF device according to the first and third embodiment of the present invention.

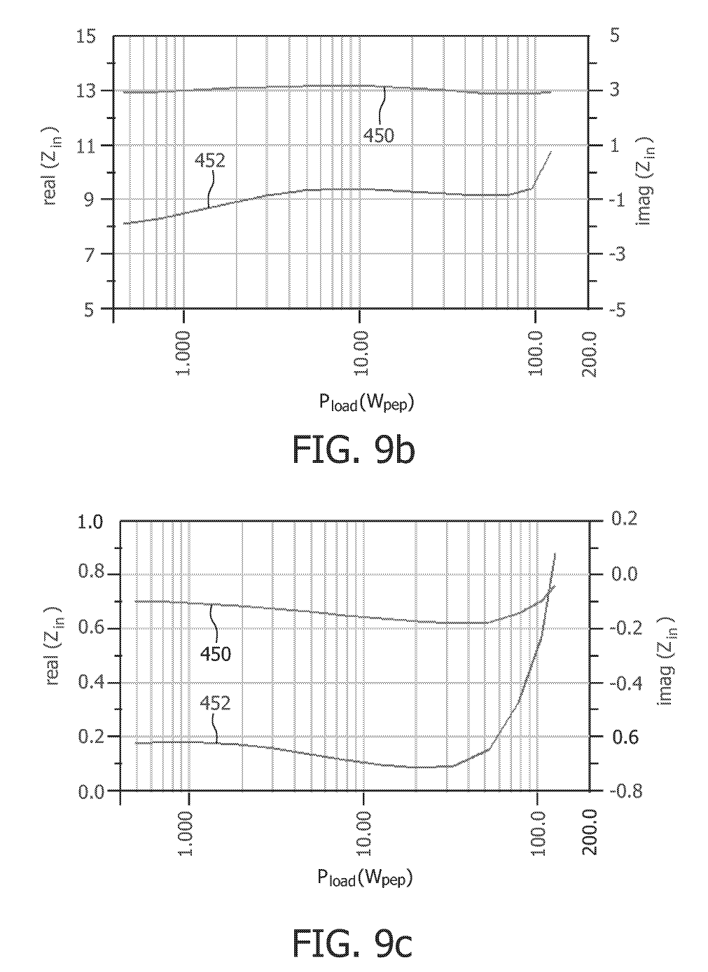

FIG. 9a to FIG. 9c show a simulated result for the obtained input impedance as a function of the power load in a 40W LDMOST model having different degrees of mutual inductive coupling between a pre-matching circuit and an output compensation circuit in an RF device according to the first and third embodiment of the present invention.

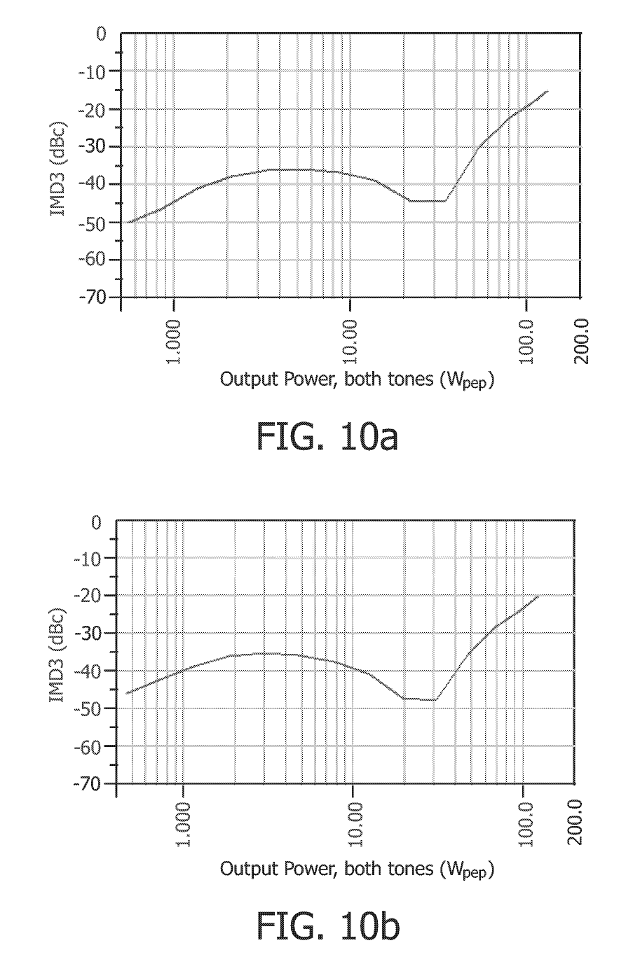

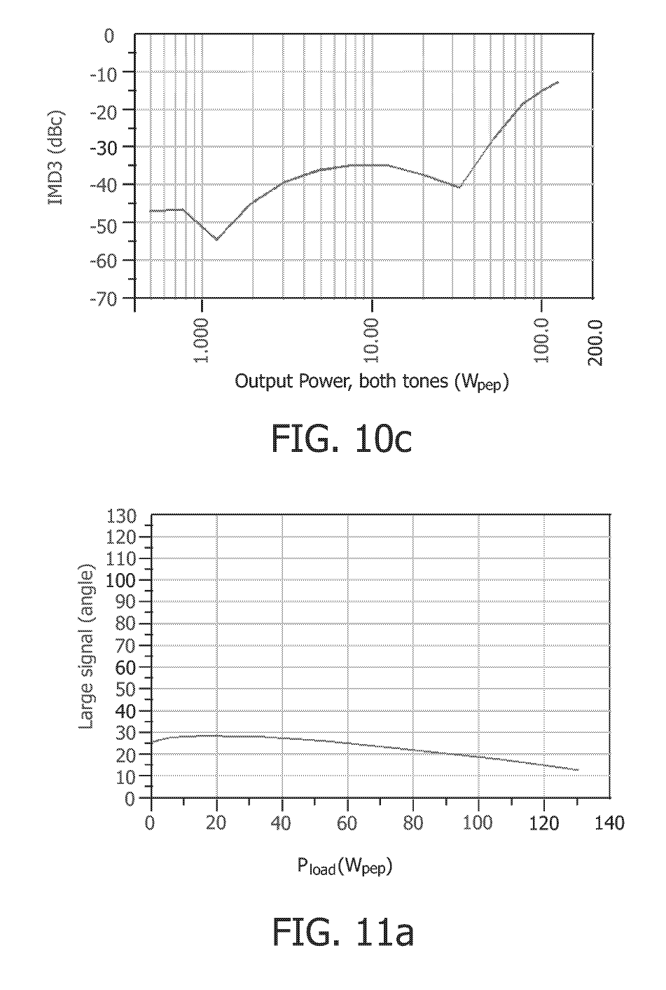

FIG. 10a to FIG. 10c show a simulated result for the obtained third order intermodulation distortion as a function of the output power in a 40W LDMOST model having different degrees of mutual inductive coupling between a pre-matching circuit and an output compensation circuit in an RF device according to the first and third embodiment of the present invention.

FIG. 11a to FIG. 11c show a simulated result for the obtained large signal as a function of the power load in a 40W LDMOST model having different degrees of mutual inductive coupling between a pre-matching circuit and an output compensation circuit in an RF device according to the first and third embodiment of the present invention.

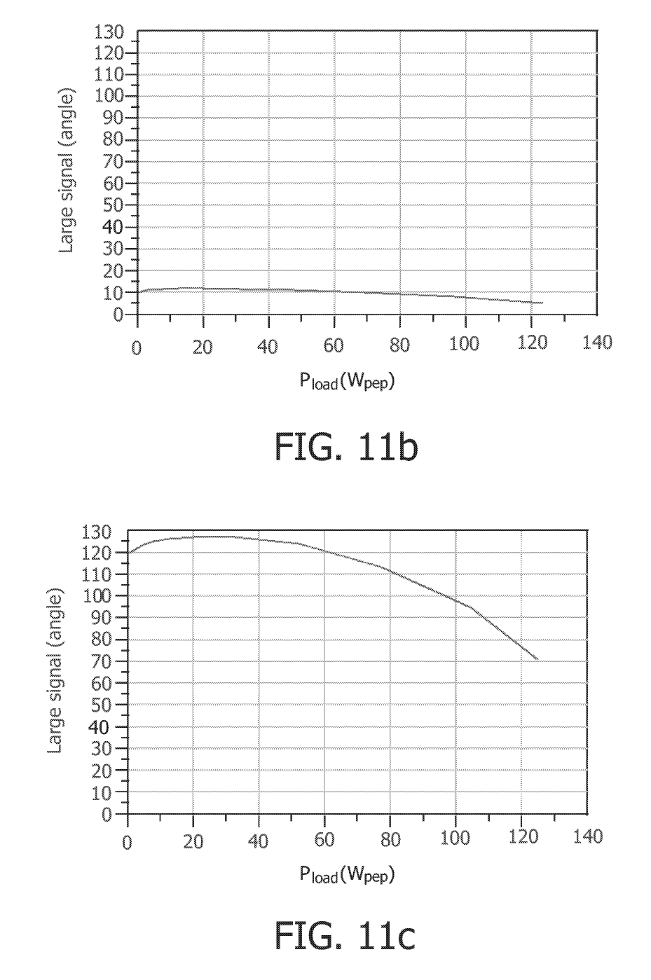

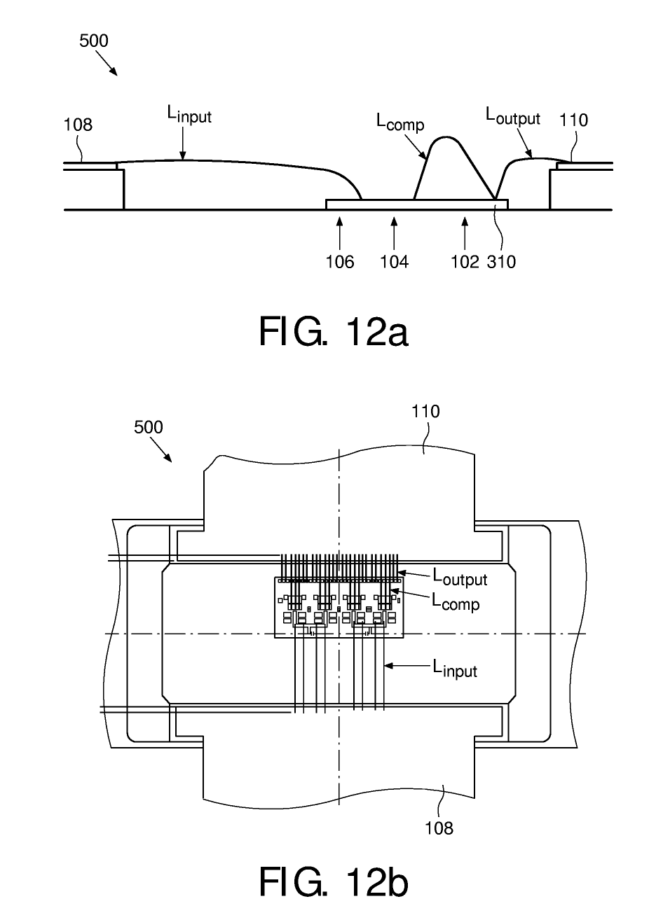

FIG. 12a and FIG. 12b indicate a cross-sectional view respectively top view of a RF device comprising an output compensation circuit physically located between the pre-matching circuit and the transistor, according to a second embodiment of the present invention.

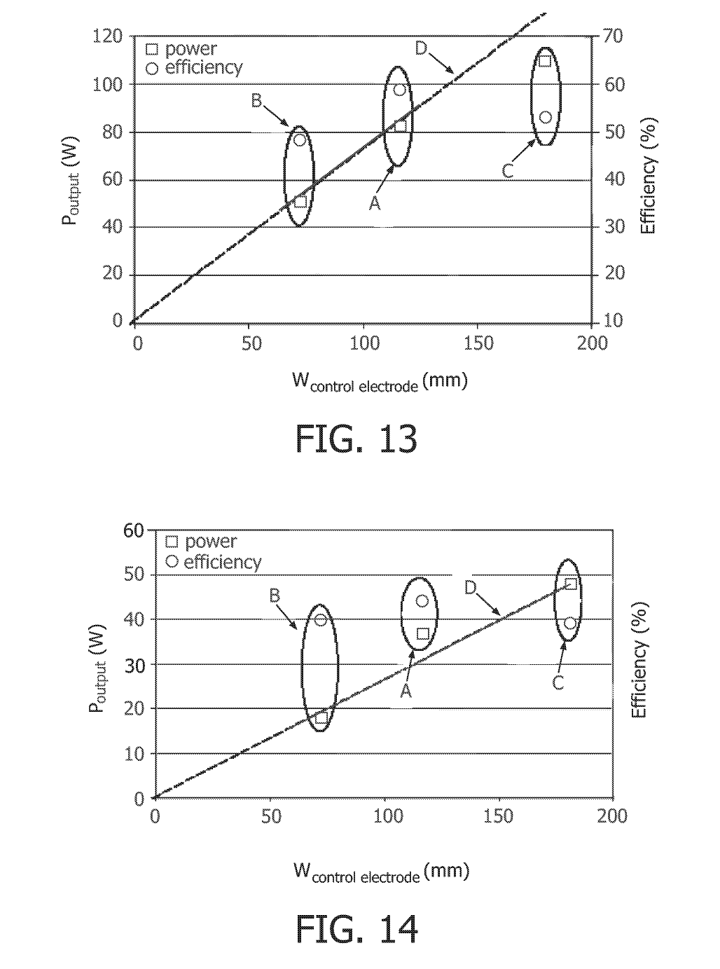

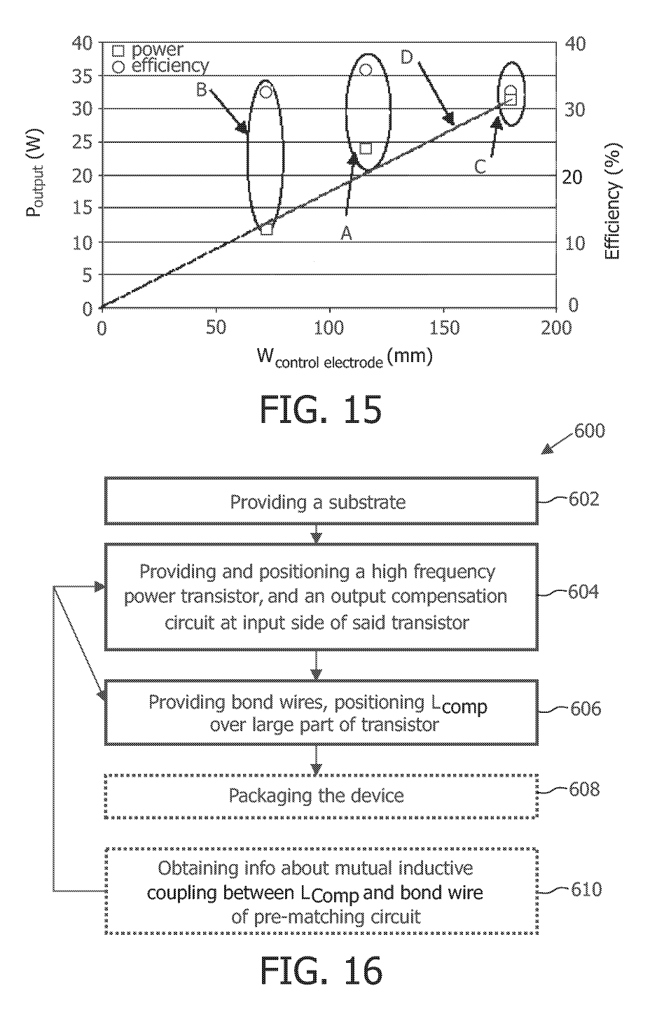

FIG. 13, FIG. 14 and FIG. 15 indicate the measured device output power and power efficiency for a radiofrequency power device according to FIG. 12b, compared to the measured output power and power efficiency for prior art RF power devices, corresponding to 1 dB compression of power gain (FIG. 13), to intermodulation distortion IMD3 of −30 dBc (FIG. 14) and to intermodulation distortion IMD3 of −40dBc (FIG. 15). The straight line at the plots indicates the case of ideal scaling of P_{—}1 dB (FIG. 13), and ideal Pout (FIG. 14, FIG. 15).

FIG. 16 shows a flow diagram of a method for fabricating a high frequency device having an output compensation circuit physically located further from the output lead than the radiofrequency transistor.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under, and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein. When explicit reference is made to the “physical location”, these terms are intentionally used for describing relative positions and the relative location of the components referred to cannot be changed as such.

In the embodiments of the present invention, a radiofrequency device will be described whereby different electronic components are provided on a substrate. The term “substrate” may include any underlying material or materials that may be used, or upon which a device, a circuit or an epitaxial layer may be formed. Alternatively, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer.

In a first embodiment, the present invention relates to a semiconductor device, such as a radiofrequency device for generating a radiofrequency (RF), amplified signal. Such a semiconductor device may be a RF power device. Radiofrequency typically is defined as a frequency between 9 kHz and 400 GHz. The device thus may operate in a frequency range between 9 kHz and 400 GHz, e.g. operate in the medium frequency range, in the high frequency range, in ultra high frequency range, in the super high frequency range, etc. A more detailed description of the RF region of the electromagnetic spectrum can e.g. be found on pages 1 to 2 of “Secrets of RF Circuit Design”, by Carr (Mc Graw-Hill Companies, Inc. 2001). The device may e.g. advantageously be used at a frequency higher than 1.8 GHz, e.g. at 18 GHz, as used in wireless telecommunications. Radiofrequency devices typically are used in various applications such as e.g. power amplifiers for radio and television broadcasting systems and for mobile communication systems. Other applications include base transmission stations (BTS), satellite terrestrial stations, mobile phones or cordless phones, transmitters used in avionics, radar, etc. The RF devices, e.g. RF power devices, according to the present invention are very useful for applications where a high efficiency and a wide bandwidth is required. An example of a RF power device according to the present embodiment is shown in FIG. 2. The RF device 100, e.g. an RF power device, comprises a RF transistor 102, e.g. RF power transistor, and an output compensation circuit 104 as components. Often, the RF device 100 may also comprise an optional pre-matching circuit 106, although the invention is not limited thereto. The RF transistor 102 and the output compensation circuit 104 and the optional pre-matching circuit 106 are all arranged in a planar fashion, e.g. on a surface of the metal flange of the transistor, packaging, heat sink or substrate.

The RF device 100 furthermore comprises an input lead 108 and an output lead 110 forming the input and output of the device, from which e.g. a packaged device may be externally connectable by this or any other means, such as e.g. a ball grid, a tab, etc. The RF transistor 102, typically provided on a substrate, may be any type of in-plane RF transistor suffering from parasitic output capacitance Cₒᵤₜt. It may be a RF power transistor. The RF transistor 102, e.g. RF power transistor, may be e.g. a field effect transistor (FET) such as e.g. a lateral diff-used metal-oxide semiconductor transistor (LDMOST) but also may be another type of transistor such as e.g. a metal-oxide semiconductor transistor (MOS), a pseudomorphic high-electron-mobility transistor (PHEMT), a bipolar junction transistor (BJT) or a heterojunction bipolar transistor (HBT). The RF transistor 102 typically comprises a first and a second main electrode and a control electrode (not shown in FIG. 2), whereby one of these main electrodes, further called the second main electrode, functions as output electrode. RF transistors and their method of fabricating are well known by a person skilled in the art. In case of a unipolar transistor, the first main electrode may be a source electrode, the second main electrode may be a drain electrode and the control electrode may be a gate electrode. The output electrode of the RF transistor 102 is connected to the output lead of the RF device 100 using bond wire(s) Lₒᵤₜₚᵤₜ. When a pre-matching circuit 106 is present, which often is the case, typically the input signal is provided through the input lead connected with bond wire(s) Lᵢₙₚᵤₜ to the pre-matching circuit 106, which typically may be a low-pass L-C-L filter configuration. The signal is further transmitted to the RF transistor 102, e.g. RF power transistor, through bond wire(s) L_{pre-match} between the pre-matching circuit 106 and the control electrode, e.g. gate electrode, of the RF transistor 102. Alternatively, the input lead may be directly connected to the control electrode of the RF transistor 102. The output compensation circuitry 104, provided in order to compensate the parasitic output capacitance Cₒᵤₜ (not shown in FIG. 2) of the RF transistor 102, may comprise any component for compensating the parasitic output capacitance Cₒᵤₜ of the output signal of the RF transistor 102. Such an output compensation circuit 104 may be implemented as an INSHIN circuit, i.e. an Internal Shunt Inductance. The output compensation circuit 104, e.g. the INSHIN circuit, comprises a compensation inductance L_{comp} grounded through a decoupling capacitor C_{comp}. The output compensation circuit 104 is connected between the RF transistor's output electrode and a ground, whereby the compensation inductance L_{comp} of the output compensation circuit 104 may be provided as the bond wire(s) that is connected to the RF transistor's output electrode. Alternatively, an additional inductance may be provided. The decoupling capacitor C_{comp} typically may be selected such that it provides a parallel resonance with the parasitic output capacitance Cₒᵤₜ (not shown in FIG. 2) at the operational frequency or frequencies of the RF transistor 102, e.g. RF power transistor. According to an aspect of the present invention, the decoupling capacitor C_{comp} of the output compensation circuit 104, e.g. the INSHIN circuit, is physically positioned at the input side of the RF transistor 102, also referred to as the RF transistor's control electrode or, in case of an unipolar transistor, the RF transistor's gate electrode, and not at the output side of the RF transistor, also referred to as the RF transistor's second main electrode or output electrode, e.g. drain electrode in case of a unipolar transistor. The decoupling capacitor C_{comp} thus is positioned closer to the device's input lead 108 with reference to the RF transistor 102, i.e. not closer to the output lead 110 of the device with reference to the RF transistor 102. In other words, the decoupling capacitor C_{comp} of the output compensation circuit 104 is physically located closer to the first main electrode and the control electrode than to the second main electrode of the RF transistor 102. The decoupling capacitor C_{comp} of the output compensation circuit 104 thus is physically located between the input lead 108 of the RF device 100 and the RF transistor 102, e.g. the first main electrode of the RF transistor 102. In other words, the inductance L_{comp} of the output compensation circuit 102 is connected to the output lead or drain of the RF transistor 102 with one end and to the ground with another end through the decoupling capacitor, which is located at the input side of the RF transistor 102, between the control electrode, e.g. gate electrode, of the transistor and the input lead 108 of the RF device 100. The RF transistor 102 thus is positioned closer to the output lead 110 of the RF device 100 than the decoupling capacitor C_{comp} of the output compensation circuitry 104. In this way, the bond wire(s) L_{comp} between the output compensation circuit 104 and the output electrode or second main electrode of the RF transistor 102, extend over the largest part of the RF transistor 102, and thus typically extends in the other direction with reference to the RF transistor 102 compared to prior art devices. The latter is shown in FIG. 3.

As described above, optionally a pre-matching circuit 106 may be provided. Such a pre-matching circuit 106 typically is connected with the input lead of the RF device 100 using bond wire(s) Lᵢₙₚᵤₜ and is connected to the control electrode, e.g. the gate electrode, of the RF transistor, e.g. RF power transistor. The pre-matching circuit 106 may furthermore consist of one, two or more components, connected with each other via bond wire(s) Lₚₘ₁, Lₚₘ₂, . . . , etc.

By selecting a specific physical location for the different components the output electrode of the RF transistor 102 can be connected to the output lead 110 of the RF device 100 using bond wire(s) Lₒᵤₜₚᵤₜ that are significantly shorter than bond wire(s) in prior art systems comprising an output compensation circuit. The latter typically depends on the height of the leads relative to the height of the transistor. Typically, due to specific design rules, the spacing between the transistor and the output compensation circuit, or more particularly the decoupling capacitor of the output compensation circuit, and between the output compensation circuit, or more particularly the decoupling capacitor C_{comp} thereof, and the output lead 110 is required to be at least 0.4 mm. So, taken into account, by way of example, a typical capacitor width of an output compensation circuit, e.g. an INSHIN capacitor width of 0.8 mm, the overall distance in prior art devices between the transistor die 102 and the output lead 110 is at least 1.6 mm (=0.4 mm+0.8 mm+0.4 mm), while for a device according to embodiments of the present invention, the distance can be decreased by 4 times to 0.4 mm.

The possibility to use short bond wire(s) Lₒᵤₜₚᵤₜ has significant advantages. It allows to obtain a high power efficiency in the RF devices for predetermined frequencies. It improves the potential operational frequency bandwidth obtained with the system. The latter improvement also is obtained due to the reduced parasitic inductance at the output. Furthermore, a wider bandwidth of the baseband decoupling, due to an about three times lower value of output bond wire(s), e.g. drain bond wire(s), is obtained. The typical bandwidth required for e.g. multi-carrier W-CDMA baseband transmission is of the order of 60 MHz, which is improved with the RF device 100 according to the embodiments of the present invention. The latter also can be seen from the simulation results shown in FIG. 8 to FIG. 11, which will be discussed in more detail further below. Furthermore, a higher reliability is obtained for the RF device 100, as the shorter output bond wire(s) Lₒᵤₜₚᵤₜ provide a better power dissipation and lower temperature of the wire(s)resulting in a more stable device. Another effect of the shorter bond wire Lₒᵤₜₚᵤₜ is the improved power efficiency due to the lower power dissipation and lower power loss. This is furthermore also supported by the shorter return RF current path located between the transistor output and the output lead 110 as the latter provides less losses. The design of the device 100 can be made more compact due to the more efficient use of area inside the package, especially in front of the transistor die, and the physical positions of the different components. The space needed in the packaging thus can be reduced or used for introducing more impedance transformation steps, such as e.g. in case of LDMOST devices, which suffer from very low input impedance, or used for other purposes. It is also an advantage that there is a lower magnetic coupling between the bond wire(s) L_{comp} of the output compensation circuit 104 and the bond wire Lₒᵤₜₚᵤₜ between the RF transistor's output electrode and the output lead 110 of the RF device 100.

FIG. 4 and FIG. 5 show alternative designs of the first embodiment of the present invention. The RF devices 200, 250, e.g. RF power devices, comprise the same components as the RF device 100 shown in FIG. 2, but the components of these devices 200, 250 have a different physical location. Whereas in the RF device 100 of FIG. 2 a weak mutual inductance coupling between the bond wire L_{comp} of the output compensation circuit 104 and the bond wire Lₚₘ₁ between the two components of a pre-matching circuit is obtained, the RF device 200 of FIG. 4 has a design such that a weak mutual inductance coupling between the bond wire L_{comp} of the output compensation circuit 104 and the bond wire L_{pre matching} connecting the pre-matching circuit 106 with the transistor 102 is obtained. The RF device 250 shown in FIG. 5, provides a design such that a strong mutual inductance coupling between the bond wire L_{comp} and the bond wire L_{pre matching} connecting the pre-matching circuit 106 with the transistor 102 is provided. It is to be noted that the above devices only are shown by way of example, and that the invention is not limited thereto. Other designs for the different components, providing a short bond wire Lₒᵤₜₚᵤₜ between the output electrode of the transistor and the output lead of the device are also within the scope of the present application. From the different designs, it can be seen that different types of mutual inductance coupling between the bond wire of the output compensation circuit 104 and a bond wire of the pre-matching circuit can be obtained.

In a second embodiment, the present invention relates to an electronic device, especially a RF device, e.g. RF power device, as described in the previous embodiment, also comprising a RF transistor 102, an output compensation circuit 104 and optionally a pre-matching circuit 106 as components, wherein at least the transistor 102 and the output compensation circuit 104 is provided on the same die. In a preferred embodiment, a pre-matching circuit 106 also is provided on the same die as the transistor. The latter is illustrated in FIG. 6, showing a RF device 300, e.g. RF power device, comprising a single die 310 whereon the RF transistor 102, the output compensation circuit 104 and the optional pre-matching circuit 106 is positioned. The latter allows for a compact design, which is advantageous as it requires less space in the packaging and allows for production of smaller devices. Standard components still may be used in these devices.

In a third embodiment, the present invention relates to a device especially a RF device according to any of the previous embodiments, e.g. an RF power device, wherein a feed-back mechanism is used, based on the specific design of the RF device according to the present invention. It is known that all parameters of amplifiers strongly depend on the available feed-back mechanisms which are always present inside the device die but which also can be introduced outside the device die. The feed-back mechanisms can typically be introduced in different ways, e.g. as positive feed-back mechanisms, negative feed-back mechanisms, feedback in series and in parallel. The impact of feed back mechanisms on a power device depends on the device's internal signal phase transfer characteristic and operation mode, i.e. whether the device operates as class A, Class AB or Class C. For example in case of AB class operation, the devices always show a variable amplitude dependent amplitude distortion (AM-AM), a variable amplitude dependent phase distortion (AM-PM) and a variable input impedance, which is undesirable for most applications. Introduction of negative feed-back then in general improves the linearity and stability of the device's parameters as a function of power and as a function of frequency. In prior art devices, introduction of feed back mechanisms, such as e.g. outside feed back mechanisms, for RF power devices typically is restricted due to the specific design of these devices and other technological restrictions. In devices according to the present invention, different types of feed back mechanisms can be introduced, based on the mutual inductive coupling between the inductance of the output compensation circuit and inductances available in the input pre-matching circuitry. This signal can be applied at any phase polarity to the inductances of one of the bond wire(s) of the pre-matching circuit 106, i.e. L_{pre match} or Lₚₘ₁, Lₚₘ₂, . . . through mutual inductive coupling, thus providing a feed back signal. The feed back signal thus is obtained through the mutual inductive coupling between the bond wire of the output compensation circuitry 104 and one of the bond wire(s) of the pre-matching circuit 106. Different types of mutual inductive coupling can be obtained depending on the specific design of the embodiments of the present invention, as is already shown by way of example in FIG. 2, FIG. 4 and FIG. 5, illustrating weak mutual inductive coupling between bond wire L_{comp} and Lₚₘ₁, weak mutual inductive coupling between bond wire L_{comp} and L_{pre match} and strong mutual inductive coupling between bond wire(s) L_{comp} and L_{pre match} respectively. Selection of the type and application point of the feed-back mechanism used typically will depend on the frequency of operation and on which RF transistor parameters need to be improved. Such a selection typically is based on an evaluation of RF transistor parameters, such as the large signal gain and phase characteristic as a function of power, i.e. amplitude dependent amplitude distortion (AM-AM) and amplitude dependent phase distortion (AM-PM) and the large signal gain and phase characteristic as a function of frequency. Such an evaluation may e.g. be done during design of a RF device and may e.g. be based on simulations of the operation of a RF device using typical software packages such as e.g. SPICE, Advanced Design Simulations (ADS), Microwave Office (AWR) etc. By the design of the RF device according to the present invention, a wide spectrum of feed-back of negative and positive nature can be provided, which provides the opportunity to improve a power transistor performance with the feedback between output and input of the device.

By way of example, in Table 1, the performance of an input matching for an LDMOS transistor device is presented. The structure consists of an RF transistor having an input gate resistance R_{g}, a gate-source capacitance C_{g-s}, an output compensation circuit and a pre-matching circuit having an bond wire L_{pre-match}, a pre-match capacitor C_{P} and a second bond wire Lᵢₙₚᵤₜ, where the RF current angles for L_{pre match} and Lᵢₙₚᵤₜ are presented. Depending on the design, the bond wire(s) of the output compensation circuit, e.g. INSHIN circuit, can be arranged in the way that they have strong mutual inductive coupling to bond wire(s) of L_{pre match}, Lₚₘ₁ or Lᵢₙₚᵤₜ, having different current amplitude and angle which in turn will make a different effect on the device performance providing a positive or negative loop feedback. The effect of physical values of the different components of the device on the pre-matching parameters are shown in table 1. The sign of the feedback depends on many factors like the forward transmission gain and reverse transmission gain of the power device, the technology used and the design, influencing the strength of the coupling between wire(s)

TABLE 1

| Pre-matching | | | | Node current | |
|---|---|---|---|---|---|
| Element | value | R (Ω) | J_{X} (jΩ) | (A) | Angle (°) |
| R_{g} | 0.4 Ω | 0.400 | 0.000 | 1.581 | 0.0 |
| C_{g-s} | 70.0 pF | 0.400 | −1.137 | 1.581 | 0.0 |
| L_{pre match} | 0.3nH | 0.400 | 2.633 | 1.581 | 0.0 |
| Cp | 30.0 pF | 17.549 | −1.797 | 0.239 | 87.2 |
| Lᵢₙₚᵤₜ | 0.2 nH | 17.549 | 0.716 | 0.239 | 87.2 |

Appropriate selection may e.g. allow to linearise the amplitude dependent phase distortion and furthermore may allow to influence, e.g. increase or decrease depending on the device technology used, the input impedance. The latter is illustrated by some exemplary simulation results for LDMOST devices at 2 GHz with different types of mutual inductive coupling according to the present invention, as shown in FIG. 8 to FIG. 11, and which will be discussed in more detail further below.

In a fourth embodiment, the invention relates to a power device especially a RF device according to any of the previous embodiments, wherein additional transformation circuits, different from the first pre-matching or first output compensation circuit, can be provided. The latter can be done due to the compact design of the RF device according to the present invention, as this provides free space. Providing additional pre-matching circuits allows to improve the operational bandwidth of the device. In FIG. 7a, by way of example, a RF device 400 is shown with an additional transformation circuit 402 at the output side of the RF transistor 102. It is to be noted that the additional transformation circuit 402 is a different circuit than the output compensation circuit 104, which can be designed in traditional way, for example as low-pass L-C-L impedance transformer. The output electrode of the transistor 102 is connected through bond wire(s) Lₒᵤₜₚᵤₜ₁ with the additional transformation circuit 402 and the additional transformation circuit 402 is connected through bond wire(s) Lₒᵤₜₚᵤₜ₂ with the output lead 110. Alternatively or in addition thereto, additional amplification means also may be provided. In FIG. 7b, an example of a two stage amplification device 420 arranged in a single standard discrete device package, such as e.g. SOT502A is shown. So, using the new suggested compensation circuit 104, a two stage power amplification device 420 can be arranged in the same standard discrete device package as used for one stage power devices, thus increasing the overall gain. The device 420, comprises, besides the standard components described in the previous embodiments, a electronic driver component 422, e.g. a driver transistor and other standard components for a two stage amplification device, such as e.g. pre-matching circuitry 424, 426.

By way of example and in order to further illustrate some advantages of the present invention, simulation and measurement results are shown for a 40W LDMOST power device with the output compensation capacitor physically located between the input lead of the device and the transistor, at 2.14 GHz. The power device used for obtaining the measurement and simulation results shown, is an amplifier of class AB. Nevertheless, it will be obvious for the person skilled in the art that the invention is not limited thereto and that the alternatively positioned output compensation circuitry, positioned as described in the above embodiments, can be advantageously used in amplifiers of different classes. The invention can e.g. used in amplifiers of class A, class C, class F, Doherty amplifiers, etc. It will be clear that the simulation and measurements results are provided by way of illustration, without the invention being limited thereto.

In a first example, simulation results were obtained for a 40W lateral double-diffused metal-oxide-semiconductor transistor (LDMOST) with a pre-matching circuitry, which may contain different components and an output compensation circuitry, whereby the output compensation capacitor is physically located between the input lead of the device and the transistor, according to the above described embodiments. RF devices with different degrees of mutual inductance coupling are simulated, using the CAD software Advanced Design System as obtainable from e.g. Agilent Technology. The non-linear Harmonic Balance simulation results allow to illustrate the effect of mutual inductive coupling between wire(s) of the output compensation circuitry and wire(s) of the pre-match circuitry. In FIG. 8a, FIG. 9a, FIG. 10a and FIG. 11a, simulation results are provided for a device wherein no mutual inductive coupling exists, i.e. with an inductive coupling constant K=0, between the bond wire L_{comp} of the output compensation circuitry and bond wire(s) of the pre-matching circuitry, In FIG. 8b, FIG. 9b, FIG. 10b and FIG. 11b simulation results are shown for a device with mutual inductive coupling K=0.5 and in FIG. 8c, FIG. 9c, FIG. 10c and FIG. 11c simulation results are shown for a device with mutual inductive coupling K=−0.5 existing between small parts of the bond wire(s) L_{pre-match} and the bond wire(s) L_{comp} of the output compensation circuit. The graphs in FIG. 8a to FIG. 8c show the power dependency of the gain, expressed in dB, FIG. 9a to FIG. 9c show the power dependency of the real part of the input impedance 450 and imaginary part of the input impedance 452 and FIG. 10a to FIG. 10b show the power dependency of the third order of the intermodulation distortion expressed in dB relative to the carrier level. The power quantity thereby used is the peak envelope power, expressed in Watt, i.e. Wₚₑₚ. Furthermore, FIG. 11a to FIG. 11b show the large signal gain as a function of the output power. From these graphs, the effect of mutual inductive coupling between the bond wire(s) of the pre-matching circuit and the output compensation circuit on different parameters of the RF device can be seen. It can be seen that for operation at the frequency for which the results are shown, the power gain can be increased, by selecting a specific degree of mutual inductive coupling. It thereby is to be noted that the resulting effect of the coupling between the bond wires depends strongly on the design of the circuitry, the operational frequency and the RF device that is used. Comparison of the input impedance as a function of the peak envelope power load Wₚₑₚ, shown in FIG. 9a to FIG. 9c, illustrates e.g. that the real part of the input impedance can be increased from 2.2Ω to 13Ω for a mutual coupling constant K=0.5, and that the real part of the input impedance can be decreased from 2.2Ω to 0.6Ω for a mutual coupling constant K=−0.5. Comparison of the large signal as a function of the peak envelope power load, shown in FIG. 11a to FIG. 11c, illustrates that for a mutual coupling constant K=0.5 a linearizing effect occurs for the amplitude modulation and phase modulation (AM/PM) characteristics. The latter illustrates that by implementing e.g. a mutual inductive coupling with coupling constant K=0.5, both the stability of the AM/PM characteristics as a function of power and the input impedance can be increased. The different effects of different mutual coupling constants on the gain and the linearity with respect to intermodulation distortion can be seen from comparison between FIG. 8a to FIG. 8c respectively FIG. 10a to FIG. 10c. These results indicate that different parameters of the RF device, such as e.g. the power gain, the input impedance and the amplitude modulation and phase modulation characteristics, can be changed, e.g. improved, in a desired way by selecting an appropriate inductive coupling coefficient and by selecting a point of feed-back signal application Lₚₘ₁ or L_{pre-match}.

By way of second example, measurement results were obtained for a RF device ((4×29) mm) as shown schematically in cross-section in FIG. 12a and in top view in FIG. 12b. It is to be noted that the results are only given by way of illustration and that the invention is not limited to the shown design of the RF device. The RF device 500 comprises a RF transistor 102, a pre-matching circuitry 106 and an output compensation circuitry 104 integrated on a single die 310. The pre-match circuitry 106 is on the one side connected to the input lead 108 of the RF device 500 with bond wire(s) Lᵢₙₚᵤₜ, in the present example 8 wire(s) in number, and on the other side connected to the control electrode of the RF transistor 102. The second main electrode or output electrode of the RF transistor 102 is connected to the output lead 110 of the RF device 500 with bond wire(s) Lₒᵤₜₚᵤₜ, in the present example 28 wire(s) in number. The output electrode of the RF transistor 102 furthermore is connected to the output compensation circuitry using bond wire(s) L_{comp}, in the present example 12 wire(s) in number. The loop height of the bond wire(s) Lᵢₙₚᵤₜ and Lₒᵤₜₚᵤₜ are measured relative to the top of the nearest lead and are maximally 0.050 mm. The bond wire(s) Lᵢₙₚᵤₜ and Lₒᵤₜₚᵤₜ are connected to the respective leads, such that they overlap maximally 0.2 mm. The loop height of the bond wire(s) L_{comp} are measured relative to the die and are maximally 0.80 mm±0.05 mm. The average thickness of the wire(s) used is 38μm. Further details of the specific design of the RF device used for obtaining measurement results are shown in FIG. 12b.

Test results are shown for the exemplary device 500, referred to as device A, having a design according to the present invention as described above, a reference device, referred to as device B, without output compensation circuitry and a RF device of type BLF4G20-130, referred to as device C, with an output compensation circuitry physically located at the output electrode of the RF transistor, as commercially available from e.g. Philips Semiconductors. FIG. 13, FIG. 14 and FIG. 15 show the drain efficiency, maximum output power at gain compression −1 dB and power output at different 2-tone 3^{rd} order intermodulation levels, i.e. IMD3=−30 dBc and IMD4=−40 dBc, for the three different sized devices A, B, C, having a gate width W_{g}=77 mm, 120 mm and 180 mm respectively, at a frequency of 2 GHz. In FIG. 13 the results are shown for a 1 dB compression gain, in FIG. 14 the results are shown for a two-tone intermodulation distortion IMD3 of −30 dB relative to the carrier level and in FIG. 15 the results are shown for an intermodulation distortion IMD4 of −40 dB relative to the carrier level. In the graphs, the output power, indicated on the left y-axis and expressed in Watt, versus the control electrode width, expressed in mm, are shown (indicated by squares) in reference to an ideal power scaling line, indicated by D. This ideal power scaling line is based on measurement of the LDMOST device having a gate width of W_{g}=77 mm thus being the smallest one and providing most reliable reference performance, with meaning that the maximum output power capability of the devices ideally should be proportional to the size of the device or gate width W_{g} and the efficiency of the devices should remain constant vs the size of the device or gate width W_{g}. Furthermore, the graphs indicate the efficiency (indicated by discs) of the devices A, B, C, indicated on the right y-axis and expressed in percentage. In FIG. 13 it can be seen that for a 1 dB compression gain, the device A according to the present invention has an output power versus control electrode width behavior that is significantly better than the device C with a prior-art type output compensation circuit design, assumed that the ideal linear power scaling as function of the control electrode width can be applied. Using the same assumptions, the obtained output power versus gate width behavior for device A furthermore also is better in the intermodulation distortion case as can be seen in FIG. 14 and FIG. 15. The efficiency of the devices, both for −1 dB compression gain and for intermodulation distortion, indicates a systematic significant better efficiency for the device A according to an embodiment of the present invention. A relative output electrode efficiency improvement at a −1 dB compression gain of more than 6% can be seen, compared to device C with a prior-art output compensation circuitry design, as well as perfect output power scaling at a compression of −1 dB, shown in FIG. 13. It furthermore can be seen from these drawings that the parasitic inductance of the bond wire(s) at the transistor output has been reduced more than 2 times.

Other arrangements for accomplishing the objectives of the RF device embodying the invention will be obvious for those skilled in the art.

In a first embodiment of the second aspect, the invention relates to a method of fabricating an electronic device, especially an electronic device for RF amplification comprising at least a RF transistor and an output compensation circuit according to any of the embodiments of the first aspect of the present invention. The method of fabricating thus allows fabrication of a RF device wherein the output compensation circuit is physically localized closer to the first main electrode and the control electrode of the transistor than to the second main electrode of the transistor, the second main electrode operating as an output electrode of the transistor. The latter allows for obtaining devices with advantages as described in the first aspect of the invention, e.g. devices having an improved efficiency and operational in a wider frequency range.

The different steps of the method 600 of fabricating a RF device according to the present invention are illustrated in the flow diagram of FIG. 16. In a first step 602, a substrate is provided. The type of substrate may be various, as described above. In a second step 604, the different components present in the RF device are introduced. The latter comprises introduction of a RF transistor and an output compensation circuit. Optionally other components such as e.g. a pre-matching circuit and additional transformation circuits also may be provided. A more detailed description of these components is provided in the embodiments of the first aspect of the present invention. The components as such are of well known design and methods for fabricating the components as such are known to the person skilled in the art. Typically these components may be provided using conventional semiconductor processing techniques on a single substrate. Alternatively, separate pieces, made on different substrates, e.g. different types of substrates, may be used. The latter can be combined using standard assembly technology. Another substrate, e.g. a low price Si substrate can then be used as inter-stage matching structure.

The physical position of the different components is such that the output compensation circuit is located closer to the control electrode, e.g. gate electrode, than it is positioned to the output electrode, drain electrode. Providing of the different components thus is performed according to a specific architectural design of the components, which allows to obtain a device having a high output power, a high efficiency and wide operational frequency bandwidth. In a further step 606, bond wire(s) are provided for interconnecting some specific components. The transistor output electrode is connected via a bond wire Lₒᵤₜₚᵤₜ to an output lead of the electronic device. The transistor output electrode furthermore is connected with a bond wire L_{Comp} to the output compensation circuit. Due to the opposite physical location of the output compensation circuit with respect to the output electrode of the transistor, the bond wire(s) L_{comp} extend over a large part of, i.e. nearly over the complete, transistor. Other bond wire(s) interconnecting e.g. the pre-matching circuit with the input lead, i.e. via bond wire Lᵢₙₚᵤₜ, and interconnecting the pre-matching circuit with the control electrode of the transistor, i.e. via bond wire L_{pre match}, are also provided. In an optional step 608, the device is packaged using conventional packaging materials and using conventional packaging techniques, thus obtaining a packaged device that is connectable through the input lead and the output lead.

In a second embodiment of this aspect of the present invention, an additional step 610 of obtaining information about the mutual inductive coupling between the bond wire L_{Comp} of the output compensation circuit and a bond wire connected to a pre-matching circuit is performed and the obtained information is used to select a specific architectural design of the different components and to provide the bond wire(s). Selecting a specific mutual inductive coupling factor allows optimization of certain parameters of the RF device. Such information can be obtained based on simulation of the operation of the high frequency device according to the present invention using well known simulation software which allows evaluation of parameters of the RF device under study. The specific coupling between the output compensation circuit and the pre-matching circuit may be used as feed-back system for further optimizing the operation of the RF device.

It is to be understood that although preferred embodiments, specific constructions and configurations, as well as materials, have been discussed herein for devices according to the present invention, various changes or modifications in form and detail may be made without departing from the scope and spirit of this invention.

1. An electronic RF device comprising an input lead and an output lead, a transistor and an output compensation circuit for compensating a parasitic output capacitance Cₒᵤₜ of said transistor, the output compensation circuit being physically located between said input lead and said transistor.

2. An electronic RF device according to claim 1, said transistor comprising a first main electrode, a second main electrode which is an output electrode and a control electrode, said control electrode being the gate electrode of a lateral diffused metal-oxide semiconductor, wherein said output electrode is connected to said output lead with a bond wire Lₒᵤtput—

3. An electronic RF device according to claim 1, wherein said output compensation circuit and said transistor are located on a single die.

4. An electronic RF device according to claim 2, wherein said output compensation circuit comprises a capacitor Cc_{O}m_{P}, said capacitor Ccₒmp being connected to the output electrode of said transistor with a bond wire Lcₒmp—

5. An electronic RF device according to claim 4, wherein an inductance determined by said bond wire Lcₒmp is used as a feedback signal.

6. An electronic RF device according to claim 2, wherein said electronic RF device furthermore comprises a pre-matching circuit, connected to said control electrode with a bond wire Lₚᵣₑ m_{atc}h—

7. An electronic RF device according to claim 6, wherein a mutual inductance coupling between the bond wire Lc_{O}m_{P} and the bond wire Lpᵣₑ match is used as part of a feedback mechanism.

8. An electronic RF device according to claim 6, said pre-matching circuit comprising a number of components interconnected by bond wire(s) Lpₘi, wherein a mutual inductance coupling between the bond wire Lc_{O}m_{P} and one of the bond wires Lₚₘi is used as part of a feedback mechanism.

9. An electronic RF device according to claim 6, wherein said RF electronic device furthermore comprises an additional transformation circuit.

10. A method of manufacturing an electronic RF device comprising, providing a substrate providing an input lead and an output lead of said electronic RF device, a RF transistor and an output compensation circuit providing bond wires between said output compensation circuit and an output electrode of said RF transistor and between said output electrode of said RF transistor and said output lead, wherein providing a RF transistor and an output compensation circuit comprises positioning said output compensation circuit physically between said input lead said RF transistor.

11. A method of manufacturing according to claim 10, wherein said method furthermore comprises providing a pre-matching circuit connected to a control electrode of said RF transistor selecting a degree of mutual inductive coupling between the bond wire L_{com}p and a bond wire connected to said pre-matching circuit.
